(19) United States
(12) Patent Application Publication
(10) Pub. No.: US 2026/0202751 A1
(43) Pub. Date: Jul. 16, 2026

(54) EXTREME ULTRAVIOLET LITHOGRAPHY LIGHT SOURCE GENERATION METHOD AND DEVICE

(71) Applicant: Shanghai Institute of Optics and Fine Mechanics, Chinese Academy of Sciences, Shanghai (CN)

(72) Inventors: Nan LIN, Shanghai (CN); Yunjie ZHANG, Shanghai (CN)

(21) Appl. No.: 19/274,460

(22) Filed: Jul. 18, 2025

(30) Foreign Application Priority Data
Jan. 13, 2025 (CN) 202510050455.2

(51) Int. Cl. G03F 7/00

(52) U.S. Cl. CPC G03F 7/70033; G03F 7/70025; G03F 7/7015

(57) ABSTRACT

A method and device for generating extreme ultraviolet lithography light source, where the method comprises generating micron-thick, uniform, and stable metallic liquid film target material in vacuum environment, and using focused 2-micron wavelength laser beam to irradiate target material to produce extreme ultraviolet (EUV) light; the device comprises 2-micron solid-state laser module, liquid film generation and maintenance module, laser focusing and energy coupling module, and EUV light collection and transmission module. Two-micron solid-state laser module is used to irradiate metallic liquid film target to generate EUV light. Liquid film generation and maintenance module ensures uniform and stable micron-thick metallic liquid film through precise temperature and flow control. Laser focusing and energy coupling module adjusts spatiotemporal distribution of laser pulses to facilitate efficient absorption of driving energy by liquid film target. EUV light collection and transmission module collects generated EUV light and transmits it to subsequent lithography process.

### CROSS-REFERENCE TO RELATED APPLICATIONS

The subject application claims priority on Chinese Patent Application No. CN202510050455.2 filed on Jan. 13, 2025 in China. The contents and subject matters of the Chinese priority application are incorporated herein by reference in the entirety.

### TECHNICAL FIELD

The present invention belongs to the field of lithography light source technology, and specifically method and device for generating an extreme ultraviolet lithography light source.

### BACKGROUND ART

In the context of the continuous development of the modern lithography technology and the increasing precision requirements for chip manufacturing, extreme ultraviolet lithography (EUVL) light sources have become the key to breaking through the bottlenecks in lithography processes. At present, the mainstream method for generating EUV light sources relies on carbon dioxide lasers to excite tin droplets to produce extreme ultraviolet light with a wavelength of 13.5 nanometers. However, the technological approach faces multiple severe challenges that hinder its widespread application in efficient, stable, and low-cost chip manufacturing.

Firstly, the carbon dioxide laser system is not only bulky and structurally complex but also extremely energy-consuming with high equipment costs. As the semiconductor industry's requirements for the power density, stability, and precision of lithography light sources continue to increase, the performance improvement of traditional carbon dioxide laser systems has gradually approached the physical limits, and technological development has entered a bottleneck period.

Secondly, the generation, precise control, and efficient coordination of tin droplets with laser pulses are another major technical challenge. The small size and rapid change characteristics of tin droplets make their stable generation and precise manipulation extremely difficult, thereby affecting the stability and consistency of extreme ultraviolet light output. The instability directly limits the yield and production efficiency in the chip manufacturing process, becoming a major obstacle to the large-scale application of EUVL technology.

### SUMMARY OF THE INVENTION

To address the limitations of the existing technologies mentioned above, the present invention provides a method and device for generating an extreme ultraviolet lithography light source. The present invention employs a metallic liquid film as the target material for the extreme ultraviolet lithography machine light source and utilizes a 2-micron solid-state laser to act on the metallic liquid film to produce extreme ultraviolet light with a wavelength of 13.5 nanometers. The present invention achieves efficient energy conversion, enhances the stability of the light source, simplifies the device structure, reduces costs, and significantly advances the development of lithography technology and the chip manufacturing industry.

Technical Solutions of the present invention is as follows.

The present invention provides a method for generating an extreme ultraviolet lithography light source, comprising the following steps of generating a metallic liquid film target material in a vacuum environment along the dripping direction, which can maintain a uniform and stable thickness at the micron level; producing a laser beam with a wavelength of 2 microns that is energy-coupled with the said metallic liquid film target material; and focusing the laser beam onto the metallic liquid film target material to maximize the absorption of laser energy by the target material and convert it into plasma radiation, thereby generating extreme ultraviolet light.

The present invention further provides a device for generating an extreme ultraviolet lithography light source, comprising a liquid film generation and stabilization module, configured to generate a metallic liquid film target material in a vacuum environment along the dripping direction and maintain its uniform and stable thickness at the micron level; a 2-micron solid-state laser module, used to emit a laser beam with a wavelength of 2 microns; and a laser focusing and energy coupling module, used to receive the laser beam emitted by the 2-micron solid-state laser module and focus it onto the metallic liquid film target material to achieve efficient energy conversion. It also adjusts the spatiotemporal distribution of the laser beam to promote the absorption of energy by the metallic liquid film target material, thereby generating extreme ultraviolet light.

Further, the device of the present invention may comprise an extreme ultraviolet light collection and transmission module, used to collect the extreme ultraviolet light and transmit it to the subsequent lithography process.

Further, the device of the present invention may comprise a vacuum pump system used to maintain the vacuum environment to ensure the vacuum level during the liquid film formation process.

Preferably, the liquid film generation and maintenance module in the present invention comprises a container, used to hold the molten metal; a temperature control system, located at the bottom of the container, comprising a temperature sensor and a heating element; a microfluidic channel, connected to the bottom outlet of the container; a micro pump, located inside the microfluidic channel, used to control the flow rate of the molten metal; a liquid film nozzle, connected to the bottom of the microfluidic channel; and an inert gas pump, located at the top of the container, used to apply pressure to make the molten metal flow out through the container, microfluidic channel, and liquid film nozzle;

In the present invention, by controlling the temperature and flow rate of the molten metal and utilizing the surface tension of the liquid itself, a stable and adjustable-thickness metallic liquid film is formed inside the container. The metallic liquid film serves as the target surface for laser action to produce extreme ultraviolet light.

In the present invention, the molten metal is tin with a purity of at least 99.9999%.

In the present invention, the container is made of quartz ceramic composite material, which has high-temperature resistance and can withstand temperatures of at least 800° C., with strong chemical stability.

In the present invention, the inner diameter of the microfluidic channel is 0.1-0.5 millimeters, and the slit width of the liquid film nozzle is 30-50 micrometers, with a length of 200-300 micrometers. These ensure the uniform and stable flow of the molten metal to the liquid film nozzle and the formation of a uniformly thick metallic liquid film.

In the present invention, the laser focusing and energy coupling module is composed of a high-numerical-aperture lens group and adaptive wavefront correction elements, with the lens group having a numerical aperture between 0.4 and 0.6.

Compared with the existing technologies, the beneficial effects of the present invention are as Follows. First, the present invention achieves simplification of equipment and cost optimization. By abandoning the complicated structure of traditional carbon dioxide lasers, the present invention uses a compact and efficient 2-micron solid-state laser as the core component. Combined with streamlined designs of the liquid film generation and other modules, the overall equipment volume is significantly reduced. The purchase cost is substantially lowered, and the complexity and cost of maintenance are also decreased, which enhances the economic benefits of the industry and increases the flexibility of equipment deployment.

Second, the present invention achieves enhanced efficiency and stability of energy conversion. The uniform and stable liquid film facilitates the absorption of laser energy. Compared with traditional tin droplet technology, the efficiency of extreme ultraviolet light generation is improved, which provides a stable light source for the replication of high-precision lithography patterns. Through the liquid film generation and maintenance module, a micron-thick metallic liquid film target material is stably generated in a vacuum environment along the dripping direction. The process increases the absorption efficiency of laser energy and thereby enhances the generation efficiency of extreme ultraviolet light.

### BRIEF DESCRIPTION OF THE DRAWINGS

FIG. 1 shows the structure of the device for generating an extreme ultraviolet lithography light source according to the present invention.

FIG. 2 shows the structure of the liquid film generation and maintenance module in the present invention.

FIG. 3 shows the structure of the nozzle in the present invention.

Reference numbers in the figures refer to the following structures: 11—2-micron laser driver light source; 12—Beam shaping and focusing system; 13—Metallic liquid film target; —14—Collection mirror; 15—Optical transmission system; 21—Gas pump; 22—Container; 23—Molten metal; 24—Temperature control system; 25—Microfluidic channel and micro pump; —26—Liquid film nozzle; —27—Metallic liquid film.

### DETAILED DESCRIPTION OF THE INVENTION

The present invention is further elaborated in conjunction with the following embodiments and accompanying drawings. The present invention can be realized in many different forms and should not be construed as limiting the scope of protection of the present invention. The terms used in the specification are intended to describe specific embodiments and are not intended to limit this application.

In the 2-micron solid-state laser module of the present invention, the core component is a 2-micron solid-state laser, which employs advanced laser gain media (such as specifically doped crystalline materials) to stably output high-power laser beams with wavelengths in the range of 1800-2100 nanometers and pulse widths flexibly adjustable within the 5-50 nanosecond range.

In the present invention, the laser is equipped with a precision power control system and an advanced beam shaping sub-module, which can precisely set the output power according to the lithography process requirements and optimize the parameters of the output beam, such as the spot shape and divergence angle, to meet the requirements for liquid film irradiation, providing a stable and compatible energy input for the subsequent generation of extreme ultraviolet light.

In the liquid film generation and maintenance module of the present invention, the container material is selected as quartz ceramic composite material, which has excellent high-temperature resistance and can withstand temperatures of at least 800° C. It also has strong chemical stability, effectively preventing chemical reactions with the contained molten metal. The molten metal contained inside is tin, which exhibits good performance in generating 13.5-nanometer extreme ultraviolet light under specific temperature and laser conditions.

In the generation method of the present invention, the container and auxiliary system design is as follows. The specially designed container has a high-precision temperature control system at the bottom, with a temperature sensor accuracy of ±0.01° C. and a heating element capable of precise temperature regulation within the range of 200-400° C. Microfluidic channels and micro pumps are located at the edge of the container. The inner diameter of the microfluidic channels is 0.1-0.5 millimeters, and the flow rate regulation accuracy of the micro pumps is ±0.01 milliliters per minute, allowing precise control of the molten metal flow rate within the range of 0.1-1 milliliters per minute.

In the present invention, utilizing the surface tension characteristics of the liquid, a liquid film is generated in a vacuum environment with a vacuum level better than 1×10⁻³ pascals.

The liquid film formation principle in the present invention is that, by adjusting the temperature control system and microfluidic channels, a liquid film with a thickness of 1.0 to 5.0 micrometers, which can be precisely adjusted according to lithography requirements, is formed inside the container under conditions where the tin solution temperature is 240-400° C. and the flow rate is 0.2-0.6 milliliters per minute. The film serves as the target surface for laser action to generate extreme ultraviolet light.

The laser focusing and energy coupling module of the present invention comprises a group of high-numerical-aperture (up to 0.4-0.6) lenses and intelligent wavefront correction elements. In one embodiment of the present invention, the laser focusing and energy coupling module of the present invention consists of a group of high-numerical-aperture (up to 0.4-0.6) lenses and intelligent wavefront correction elements. The lens group focuses the 2-micron laser beam onto the liquid film to increase the energy density.

In the multi-layer film reflective mirror group surrounding the liquid film in the present invention, the film layers are designed according to the reflection characteristics of extreme ultraviolet light (using high reflectivity materials and optimized deposition processes) to achieve high reflectivity at the 13.5-nanometer wavelength. The mirror group is designed with an asymmetric optical surface to efficiently collect extreme ultraviolet light and focus it into a high-vacuum light guide pipe.

FIG. 1 is a structural diagram of the device for generating an extreme ultraviolet lithography light source according to the present invention. As shown in the figure, the device comprises a 2-micron solid-state laser 11, a laser focusing and energy coupling module 12, a liquid film generation and maintenance module 13, and an extreme ultraviolet light collection 14 and transmission module 15. The 2-micron laser driver light source 11 emits a single-pulse, high-energy Gaussian beam, the pulse width and energy of which can be adjusted. The Gaussian beam passes through the beam shaping and focusing system 12 and strikes the metallic liquid film target 13 in the optimal form. The thickness of the metallic liquid film target is adjustable. The extreme ultraviolet light generated by plasma radiation is collected and focused into the optical transmission system 15 by the collection mirror 14.

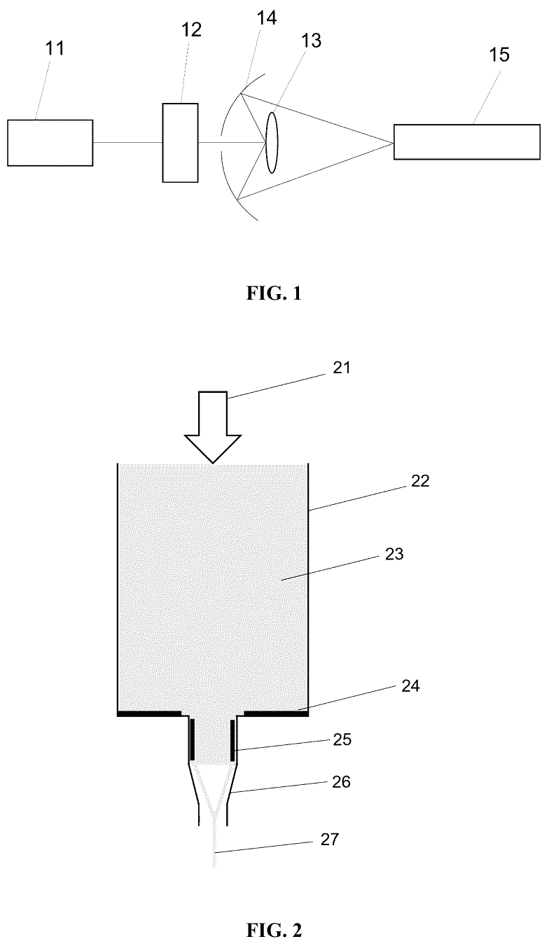

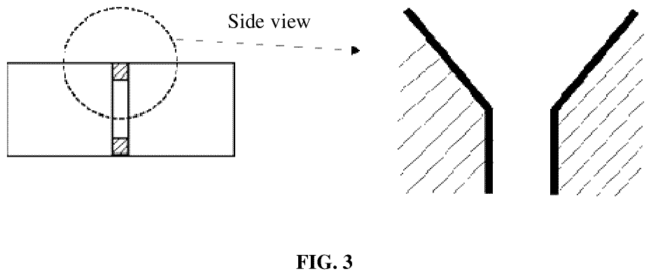

FIG. 2 shows the specific structure of the liquid film generation device, which comprises a gas pump 21; a quartz ceramic composite container 22; molten metal 23; a high-precision temperature control system 24; microfluidic channels and micro pumps 25; a liquid film nozzle 26; and a metallic liquid film 27. The gas pump 21 applies pressure from an inert gas to drive the overall flow of the liquid. The quartz ceramic composite container 22 has high-temperature resistance and can withstand temperatures of at least 800° C. with strong chemical stability and is used to hold molten metal inside. The tin metal solution 23 has a purity of 99.9999%. The high-precision temperature control system 24, located at the bottom of the container, has a temperature sensor accuracy of ±0.01° C. and a heating element that can regulate the temperature within the range of 200° C.-400° C. The microfluidic channels and micro pumps 25, with microfluidic channels located at the edge of the container and an inner diameter of 0.1-0.5 millimeters, have a flow rate regulation accuracy of ±0.01 milliliters per minute for controlling the flow rate of the molten metal within the range of 0.1-1 milliliters per minute. The liquid film 27 is generated through the nozzle 26, with a film width of 1.0-5.0 millimeters and a thickness of 1.0-5.0 micrometers.

FIG. 3 is a structural diagram of the nozzle used in the present invention, where the slit width of the nozzle is 30-50 micrometers and the length is 200-300 micrometers.

The present invention provides a lithography light source device that generates extreme ultraviolet light by irradiating a metallic liquid film with a 2-micron solid-state laser. The device uses a 2-micron driver light source, which, after passing through the laser focusing and energy coupling module, irradiates the metallic liquid film target generated by the liquid film generation device to produce extreme ultraviolet light radiation. However, the metal used in this device is not limited to tin; it is also applicable to gallium-indium-tin alloys, gallium-zinc alloys, or other material combinations that have been experimentally verified to be conducive to the efficient generation of extreme ultraviolet light. In addition, the liquid film generation device in the present invention comprises but is not limited to the above structure; it encompasses all structures capable of generating the same liquid film.

The present invention has the advantages of reducing energy consumption, improving efficiency and stability, and provides strong impetus for the vigorous development of lithography technology and the chip manufacturing industry.

We claim:

1. A method for generating an extreme ultraviolet lithography light source, comprising:
generating a metal liquid film target material in a dripping direction in a vacuum environment, wherein the metal liquid film target material is capable of maintaining uniform and stable micro-level thickness;
generating a laser beam with a 2-micrometer wavelength, wherein the laser beam is energy-coupled with the metal liquid film target material; and
focusing and bombarding the laser beam on the metal liquid film target material, so that laser energy is absorbed to a maximum extent by the metal liquid film target material and is converted into plasma radiation, thereby generating an extreme ultraviolet.

2. A device for generating an extreme ultraviolet lithography light source, comprising:
a liquid film generating and maintaining module configured to generate a metal liquid film target material in a dripping direction in a vacuum environment and maintain a uniform and stable micro-level thickness of the metal liquid film target material;
a 2-micrometer solid laser module configured to emit a laser beam with a 2-micrometer wavelength; and
a laser focusing and energy coupling module configured to receive the laser beam emitted by the 2-micrometer solid laser module and to focus and bombard the laser beam on the metal liquid film target material to achieve efficient energy conversion and to adjust time-space distribution of the laser beam to promote absorption of the metal liquid film target material to energy, thereby generating an extreme ultraviolet.

3. The device of claim 2, further comprising:
an extreme ultraviolet collection and transmission module configured to collect the extreme ultraviolet and transmit the extreme ultraviolet to a subsequent lithography process.

4. The device of claim 2, wherein the liquid film generating and maintaining module comprises:
a container configured to contain a molten metal;
a temperature control system disposed on the bottom of the container and comprising a temperature sensor and a heating element;
a microfluidic channel connected with a bottom outlet end of the container;
a micropump disposed in the microfluidic channel and configured to control a flow velocity of the molten metal;
a liquid film nozzle connected with the bottom of the microfluidic channel; and
an inert gas pump disposed on the top of the container and configured to apply an air pressure so that the molten metal flows out via the container, the microfluidic channel and the liquid film nozzle;
by controlling the temperature and flow velocity of the molten metal and utilizing a surface tension of the liquid itself, the molten metal forms a layer of stable and thickness-adjustable metal liquid film in the container, wherein the metal liquid film is used as a target surface for laser action so as to generate the extreme ultraviolet.

5. The device of claim 4, wherein the molten metal is tin with a purity that reaches 99.9999%.

6. The device of claim 4, wherein the container is made of a quartz and ceramic composite so as to be resistant to a high temperature, capable of withstanding a high temperature of at least 800° C., and high in chemical stability.

7. The device of claim 4, wherein the microfluidic channel has an internal diameter of 0.1-0.5 millimeter, and the liquid film nozzle has a slit width of 30-50 micrometers and a length of 200-300 micrometers, which ensures that the molten metal flows to the liquid film nozzle uniformly and stably and forms a metal liquid film with uniform thickness.

8. The device of claim 2, wherein the laser focusing and energy coupling module comprises a lens group with a high numerical aperture and an adaptive wavefront correction element, and the high numerical aperture of the lens group ranges from 0.4-0.6.

9. The device of claim 2, further comprising:
a vacuum pump system configured to maintain the vacuum environment so as to guarantee a vacuum degree in a process of liquid film formation.
